(19) United States
(12) Patent Application Publication
(10) Pub. No.: US 2022/0293628 A1
(43) Pub. Date: Sep. 15, 2022

(54) MEMORY DEVICE AND METHOD FOR MANUFACTURING THE SAME AND METHOD FOR OPERATING THE SAME

(71) Applicant: MACRONIX INTERNATIONAL CO., LTD., Hsinchu (TW)

(72) Inventors: Wei-Chen Chen, Taoyuan City (TW); Hang-Ting Lue, Hsinchu (TW)

(21) Appl. No.: 17/249,701

(22) Filed: Mar. 10, 2021

(51) Int. Cl. H01L 27/11582; H01L 27/11556; H01L 27/11519; H01L 27/11565; G11C 16/30; G11C 16/26; G11C 16/14

(52) U.S. Cl. CPC H01L 27/11582; H01L 27/11556; H01L 27/11519; H01L 27/11565; G11C 16/30; G11C 16/26; G11C 16/14

(57) ABSTRACT

A memory device includes a stack and a plurality of memory strings respectively penetrating the stack along the first direction and including adjacent ones of the first memory string and the second memory string. The first memory string and the second memory string include conductive pillars (including first to third conductive pillars), channel structures, and memory structures. The first memory string and the second memory string share the second conductive pillar. The channel structures include first to fourth channel layers respectively extending along the first direction. The first channel layer and the second channel layer correspond to the first memory string and are separated from each other. The third channel layer and the fourth channel layer correspond to the second memory string and are separated from each other. The memory structures are disposed between the stack and the channel structures.

### BACKGROUND OF THE INVENTION

### Field of the Invention

The invention relates in general to a memory device and a method for manufacturing the same and a method for operating the same, in particular to a three-dimensional memory device and a method for manufacturing the same and a method for operating the same.

### Description of the Related Art

Recently, since the non-volatile memory has the advantage that the stored data will not disappear when the current is turned off, people's demand for it is increasing. With more and more applications nowadays, how to provide memory devices with higher storage capacity has become one of the important research directions.

### SUMMARY OF THE INVENTION

The invention relates in general to a memory device and a method for manufacturing the same and a method for operating the same.

According to an embodiment of the present invention, a memory device is provided. The memory device includes a stack and a plurality of memory strings. The stack is formed on a substrate, and the stack includes a plurality of insulating layers and a plurality of conductive layers stacked alternately. The memory strings respectively penetrate the stack along a first direction, and the memory strings include a first memory string and a second memory string that are adjacent to each other. The first memory string and the second memory string include a plurality of conductive pillars, a plurality of channel structures, and a plurality of memory structures. The conductive pillars include a first conductive pillar, a second conductive pillar, and a third conductive pillar, which respectively extend along the first direction and are electrically isolated from each other. The second conductive pillar is disposed between the first conductive pillar and the third conductive pillar, and the first memory string and the second memory string share the second conductive pillar. The channel structures include a first channel layer, a second channel layer, a third channel layer, and a fourth channel layer that respectively extend along the first direction, wherein the first channel layer and the second channel layer correspond to the first memory string and are coupled to the first conductive pillar and the second conductive pillar, and the first channel layer and the second channel layer are separated from each other. The third channel layer and the fourth channel layer correspond to the second memory string and are coupled to the second conductive pillar and the third conductive pillar, and the third channel layer and the fourth channel layer are separated from each other. The memory structure is disposed between the stack and the channel structures.

According to another embodiment of the present invention, a method for manufacturing a memory device is provided. The method includes the following steps. Firstly, a laminated structure is provided on a substrate. The laminated structure includes a plurality of insulating layers and a plurality of sacrificial layers stacked alternately. Next, a plurality of openings are formed. The openings penetrate the laminated structure along a first direction. Then, a channel material and an insulating material are sequentially filled in the openings. Then, portions of the channel material, portions of the insulating material, portions of the insulating layers and portions of the sacrificial layers are removed along the first direction to form a plurality of extending holes between adjacent ones of the openings and the outermost two sides of the openings, and remaining portions of the channel material forms a plurality of channel structures connected to the extending holes, wherein the extending holes and the openings are alternately disposed along a second direction and are connected to each other, the second direction being perpendicular to the first direction. After that, a conductive material is filled in the extending holes to form a plurality of conductive pillars. The conductive pillars include a first conductive pillar, a second conductive pillar, and a third conductive pillar. The second conductive pillar is disposed between the first conductive pillar and the third conductive pillar. After that, the sacrificial layers are removed to expose portions of the conductive pillars and the channel structures. A plurality of memory structures and a plurality of conductive layers alternately stacked with the insulating layer are sequentially formed at positions where the sacrificial layers are removed. The insulating layers and the conductive layers form a stack. The memory structures are disposed between the stack and the channel structures. Each of intersections of the memory structures, the channel structures, and the conductive layers forms a memory cell, and a plurality of the memory cells form a plurality of memory strings extending along the first direction respectively, and the memory strings include a first memory string and a second memory string adjacent to each other, wherein the first memory string and the second memory string share the second conductive pillar.

According to a further embodiment of the present invention, a method for manufacturing a memory device is provided. The method includes the following steps. Firstly, a laminated structure is provided on a substrate. The laminated structure includes a plurality of insulating layers and a plurality of sacrificial layers stacked alternately. Next, a plurality of openings are formed. The openings penetrate the laminated structure along a first direction. Then, a memory material, a channel material and an insulating material are sequentially filled in the openings. Then, portions of the channel material, portions of the insulating material, portions of the insulating layers and portions of the sacrificial layers are removed along the first direction to form a plurality of extending holes disposed between adjacent ones of the openings and disposed at the outermost two sides of the openings, remaining portions of the memory material forming a plurality of memory structures, wherein the extending holes and the openings are alternately disposed along a second direction and are connected to each other, the second direction is perpendicular to the first direction. After that, a conductive material is filled in the extending holes to form a plurality of conductive pillars. The conductive pillars include a first conductive pillar, a second conductive pillar, and a third conductive pillar. The second conductive pillar is disposed between the first conductive pillar and the third conductive pillar. After that, the sacrificial layers are removed to expose portions of the conductive pillars and the memory structures. A plurality of conductive layers alternately stacked with the insulating layer are formed at positions where the sacrificial layers are removed. The insulating layers and the conductive layers form a stack. The memory structures are disposed between the stack and the channel structures. Each of intersections between the memory structures, the channel structures, and the conductive layers forms a memory cell, and a plurality of the memory cells form a plurality of memory strings extending along the first direction respectively, and the memory strings include a first memory string and a second memory string adjacent to each other, wherein the first memory string and the second memory string share the second conductive pillar.

According to another embodiment of the present invention, a method for operating a memory device is provided. The method includes providing a memory device as described above. If a read operation, a programming operation or an erase operation is to be performed on a specific memory cell in the second memory string, a first voltage is applied to the second conductive pillar, a second voltage is applied to the third conductive pillar, a third voltage is applied to the conductive layer coupled to the specific memory cell, and a fourth voltage is applied to the conductive layers not coupled to the specific memory cell, wherein an absolute value of the third voltage is greater than an absolute value of the fourth voltage.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIGS. 1A to 5B are schematic diagrams of a method for manufacturing a memory device according to an embodiment of the present invention;

FIG. 6 is a top view of a memory device according to a further embodiment of the present invention;

FIG. 7 is a top view of a memory device according to a further embodiment of the present invention;

FIG. 8 is a top view of a memory device according to a further embodiment of the present invention;

FIGS. 9A to 13B are schematic diagrams illustrating a method for manufacturing a memory device according to a further embodiment of the present invention;

FIGS. 14-16 show equivalent circuit diagrams of a method for operating a memory device; and

FIGS. 17-19 show simulation results when a programming operation is performed to a first bit of a specific memory cell.

### DETAILED DESCRIPTION OF THE INVENTION

In the following detailed description, for the convenience of explanation, various specific details are provided to understand the embodiments of the present disclosure as a whole. However, it should be understood that one or more embodiments can be implemented without employing these specific details. In other cases, in order to simplify the drawings, the known structures and components are shown in schematic diagrams.

The memory device and a method for manufacturing the same, and a method for operating the same will be described below. For ease of explanation, the following embodiments will particularly take 3D AND flash memory as an example. However, the present invention is not limited to this.

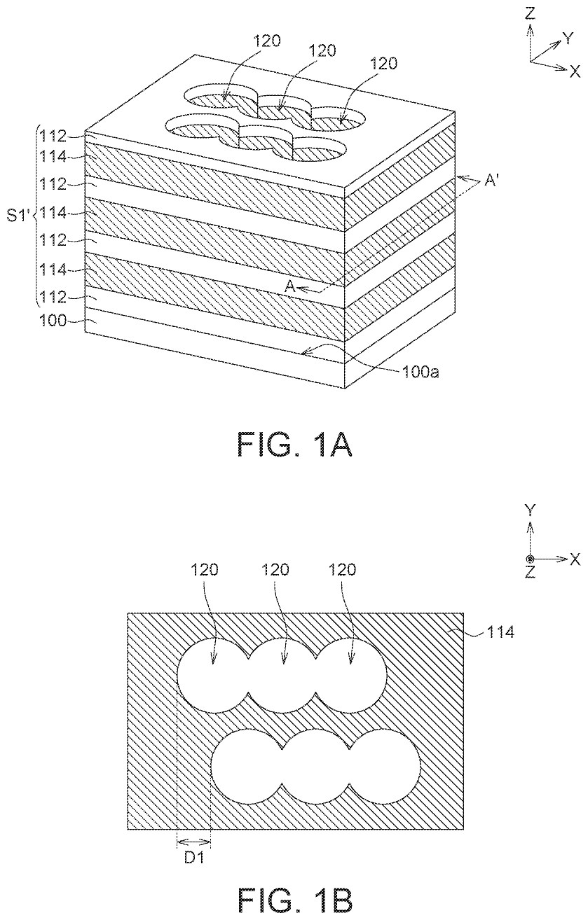

FIGS. 1A to 5B show schematic diagrams of a method for manufacturing a memory device 10 according to an embodiment of the present invention. FIGS. 1A, 2A, 3A, 4A, and 5A show three-dimensional views of the method for manufacturing the memory device 10, that is, three-dimensional views formed by a first direction (for example, Z direction), a second direction (for example, a X direction), and a third direction (for example, Y direction); FIGS. 1B, 2B, 3B, 4B, and 5B show cross-sectional views taken along line A-A′ of FIGS. 1A, 2A, 3A, 4A, and 5A respectively, that is, top views formed by the second direction (for example, X direction) and the third direction (for example, Y direction). The first direction, the second direction, and the third direction may be intersected with each other, for example, are perpendicular to each other.

Firstly, referring to FIGS. 1A and 1B at the same time, a laminated structure S1′ is provided on the upper surface 100a of a substrate 100. The laminated structure S1′ includes a plurality of insulating layers 112 and a plurality of sacrificial layers 114 alternately stacked along the first direction (for example, Z direction, or a normal direction of an upper surface 100a of the substrate 100). The insulating layers 112 and the sacrificial layers 114 are formed, for example, by deposition processes. Thereafter, a plurality of openings 120 penetrating the laminated structure S1′ along the first direction (for example, Z direction) are formed by an etching process. The bottom of each of the openings 120 exposes a portion of the upper surface 100a of the substrate 100. A portion of the openings 120 are disposed along the second direction and connected to each other to form a row of openings 120. The openings 120 in different rows are separated along the third direction, and there is an offset distance D1 in the second direction between two adjacent rows of the openings 120. In FIGS. 1A and 1B, only 2 rows of openings 120 are exemplarily shown, and each row of openings 120 includes 3 openings 120. However, the number of rows of openings 120 in the present invention and the number of openings 120 included in each row of openings 120 are not limited thereto. The openings 120 may also be referred to as vertical channel openings. In other embodiments, a portion of the openings 120 are disposed along the second direction to form a row of openings 120, but the openings 120 in the same row are not connected to each other.

In the present embodiment, the openings 120 have a circular cross-section in the top view of FIG. 1B, but the present invention is not limited thereto. The cross-section of the openings 120 in the top view of FIG. 1B may be oval, rectangular or other suitable geometric shapes.

In some embodiments, the substrate 100 is, for example, a dielectric layer (such as, a silicon oxide layer), a silicon substrate or other suitable substrate. The insulating layers 112 may be, for example, oxide layers, and the oxide layers may include silicon dioxide. The sacrificial layers 114 may be, for example, nitride layers, and the nitride layers may include silicon nitride. In the present embodiment, the top and bottom layers of the laminated structure S1′ are insulating layers 112, and the laminated structure S1′ includes four insulating layers 112 and three sacrificial layers 114, but the present invention is not limited to this. The number of the insulating layers 112 and the sacrificial layers 114 can be adjusted according to requirements.

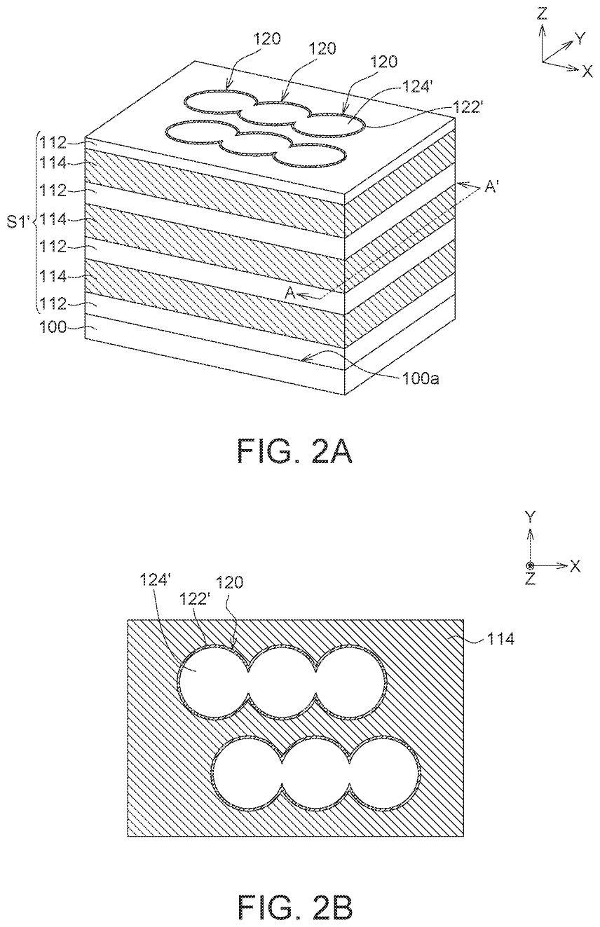

Next, referring to FIGS. 2A and 2B at the same time, a channel material 122′ and an insulating material 124′ are filled in the opening 120 in sequence. For example, the channel material 122′ can be formed on the sidewalls of the openings 120 by a deposition process, the channel material 122′ exposes a portion of the substrate 100, and the channel material 122′ is conformal to the shape of the openings 120, and then the insulating material 124′ is filled in the opening 120 having the channel material 122′ by a deposition process.

In some embodiments, the channel material 122′ may include undoped polysilicon. The insulating material 124′ may include silicon oxide, such as silicon dioxide.

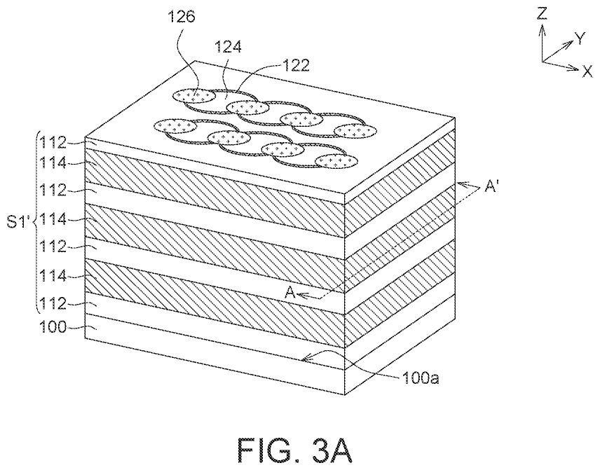

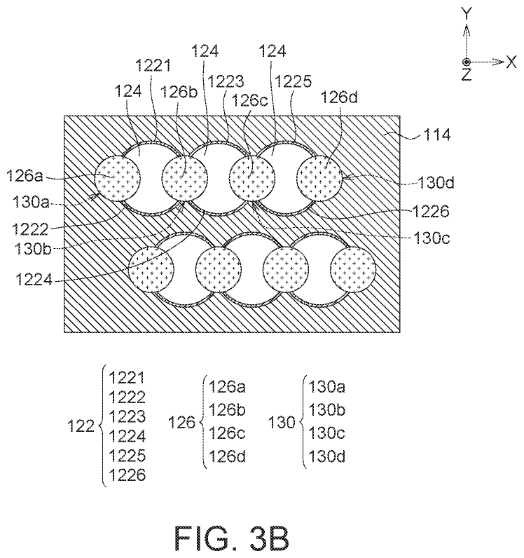

Then, referring to FIGS. 3A and 3B, portions of the channel material 122′, portions of the insulating material 124′, portions of the insulating layers 112, and portions of the sacrificial layers 114 are removed along the first direction so as to form a plurality of extending holes 130 disposed between adjacent openings 120 and disposed at two outermost sides of the openings 120. The remaining portions of the channel material 122′ form a plurality of channel structures 122 connected to the extending holes 130, and the remaining portions of the insulating material 124′ form a plurality of insulating pillars 124 disposed between the extending holes 130 and the channel structures 122, wherein the extending holes 130 and the openings 120 may be alternately disposed along the second direction and connected to each other.

For example, the extending holes 130 in the same row include extending holes 130b and 130c disposed at the center points of the borders of adjacent ones of the openings 120, the extending hole 130a disposed on the leftmost side of the openings 120, and the extending hole 130d disposed on the rightmost side of the openings 120. For example, the connection line between the center points of the extending holes 130a-130d penetrates the center points of the openings 120. A diameter of the extending hole 130 is smaller than a diameter of the openings 120. Thereafter, a conductive material is filled in the extending holes 130 to form a plurality of conductive pillars 126, wherein the conductive material is, for example, doped polysilicon. In the present embodiment, the conductive pillars 126 may include a first conductive pillar 126a, a second conductive pillar 126b, a third conductive pillar 126c, and a fourth conductive pillar 126d. The channel structures 122 may include a first channel layer 1221, a second channel layer 1222, a third channel layer 1223, a fourth channel layer 1224, a fifth channel layer 1225, and a sixth channel layer 1226.

In some embodiments, after the conductive pillars 126 are formed, a planarization process may be performed, for example, the planarization process is Chemical-Mechanical Planarization (CMP).

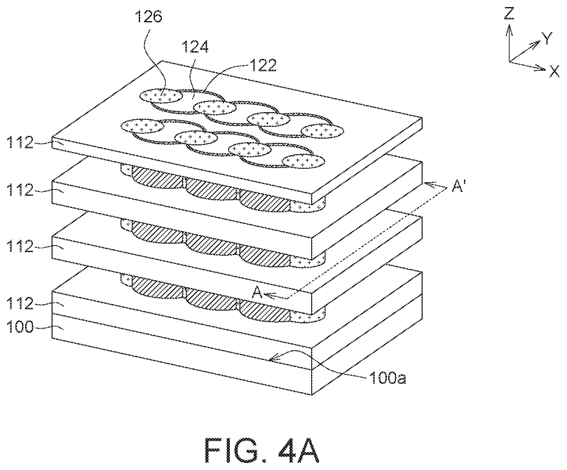

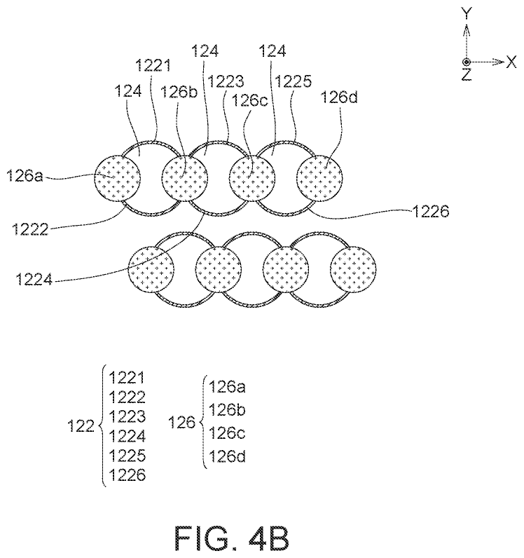

Next, referring to FIGS. 4A and 4B at the same time, the sacrificial layers 114 are removed to expose portions of the conductive pillars 126 and the channel structures 122. For example, the sacrificial layers 114 can be removed by a selective etching process, and the insulating layers 112 are remained.

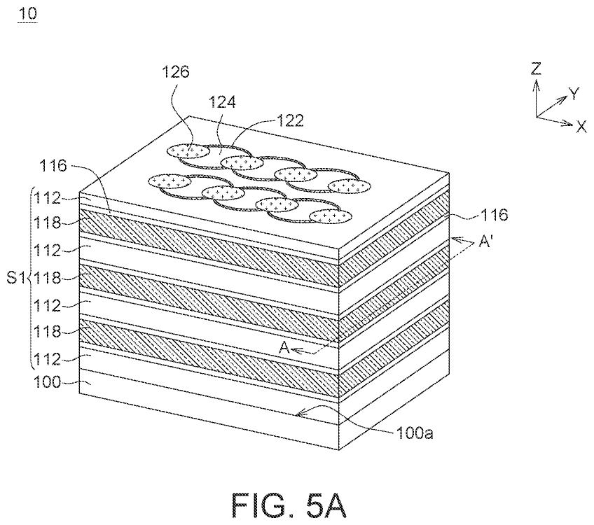

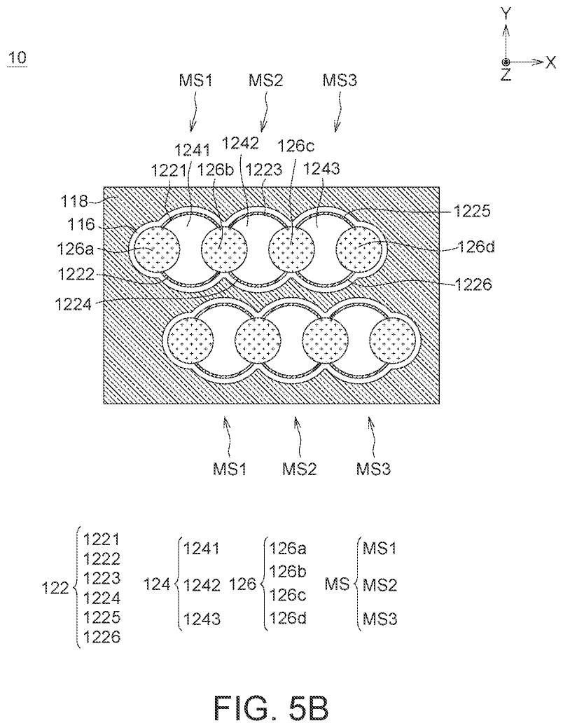

Afterwards, referring to FIGS. 5A and 5B at the same time, a plurality of memory structures 116 and a plurality of conductive layers 118 alternately stacked with the insulating layers 112 are sequentially formed at the positions where the sacrificial layers are removed, and the insulating layers 112 and the conductive layers 118 form a stack S1. In this way, the memory device 10 is formed. For example, after the sacrificial layers 114 are removed, a plurality of lateral openings exposing portions of the conductive pillars 126 and the channel structures 122 are formed. After the memory structures 116 conformal to the lateral openings, the conductive pillars 126 and the channel structures 122 are formed by a deposition process, conductive layers 118 are formed in the lateral openings having the memory structures 116 by a deposition process. Each of the intersections between the memory structures 116, the channel structures 122, and the conductive layers 118 forms a memory cell, and the plurality of memory cells form a plurality of memory strings MS extending along the first direction. In the present embodiment, the memory strings MS in the same row includes a first memory string MS1, a second memory string MS2, and a third memory string MS3 that are adjacent to each other. However, the present invention is not limited thereto. In some embodiments, the memory structures 116 may be a composite layer formed of an oxide layer-nitride layer-oxide layer, a ferroelectric material layer, or other suitable memory layer.

As shown in FIGS. 5A and 5B, the memory device 10 includes a stack S1 formed on a substrate 100 and a plurality of memory strings MS. The stack S1 includes a plurality of insulating layers 112 and a plurality of conductive layers 118 stacked alternately. The memory strings MS penetrate the stack S1 along the first direction, respectively. The memory strings MS form a plurality of rows of memory strings MS extending in the second direction (for example, X direction) on the substrate 100, and the adjacent rows of memory strings MS are separated from each other in the third direction (for example, Y direction). In the present embodiment, the memory strings MS in the same row include a first memory string MS1, a second memory string MS2, and a third memory string MS3 that are adjacent to each other. However, the number of the memory strings MS in the same row in the present invention is not limited thereto. The first memory string MS1, the second memory string MS2, and the third memory string MS3 include a plurality of conductive pillars 126, a plurality of channel structures 122, and a plurality of memory structures 116.

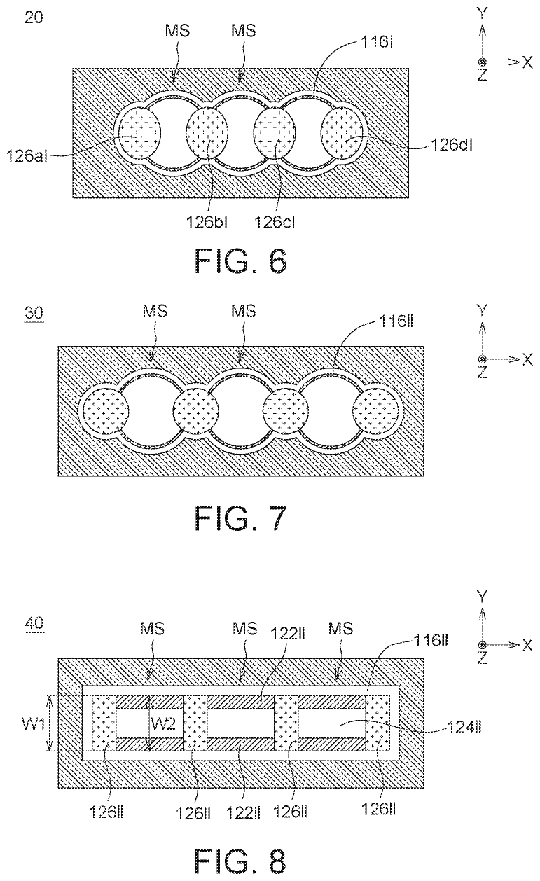

In some embodiments, the conductive pillars 126 are disposed on opposite sides of the corresponding memory string MS, for example. The conductive pillars 126 include a first conductive pillar 126a, a second conductive pillar 126b, a third conductive pillar 126c, and a fourth conductive pillar 126d that extend along the first direction and are electrically isolated from each other. The second conductive pillar 126b is disposed between the first conductive pillar 126a and the third conductive pillar 126c, and the third conductive pillar 126c is disposed between the second conductive pillar 126b and the fourth conductive pillar 126d. As shown in FIGS. 5A and 5B, the cross-sections of the first conductive pillar 126a, the second conductive pillar 126b, the third conductive pillar 126c, and the fourth conductive pillar 126d are circular, but the present invention is not limited thereto. The cross-sections of the first conductive pillar 126a, the second conductive pillar 126b, the third conductive pillar 126c, and the fourth conductive pillar 126d may be oval (as shown in FIG. 6), rectangular (as shown in FIG. 8) or other suitable shapes. The first conductive pillar 126a, the second conductive pillar 126b, the third conductive pillar 126c, and the fourth conductive pillar 126d may be electrically connected to different bit lines (not shown), respectively.

Referring back to FIGS. 5A and 5B, the first conductive pillar 126a and the second conductive pillar 126b can be used as a drain or a source of the first memory string MS1; the second conductive pillar 126b and the third conductive pillar 126c can be used as a drain or a source of the second memory string MS2; the third conductive pillar 126c and the fourth conductive pillar 126d can be used as a drain or a source of the third memory string MS3. In an embodiment, when the first conductive pillar 126a serves as a source of the first memory series MS1 and the second conductive pillar 126b serves as a drain of the first memory string MS1, the second conductive pillar 126b may serve as a source of the second memory string MS2; when the first conductive pillar 126a serves as a drain of the first memory string MS1 and the second conductive pillar 126b serves as a source of the first memory string MS1, the second conductive pillar 126b may serve as a drain of the second memory string MS2. In other words, the first memory string MS1 and the second memory string MS2 share the second conductive pillar 126b; the second memory string MS2 and the third memory string MS3 share the third conductive pillar 126c. Since the second conductive pillar 126b and the third conductive pillar 126c can be used as a drain and a source at the same time, and are connected to the corresponding bit lines, the memory device 10 can be referred to a virtual-ground-array 3D AND memory device. Compared with the comparative example in which the memory strings are separated from each other and do not share any conductive pillars, since adjacent memory strings in the memory device 10 of the present invention can share a conductive pillar, a pitch formed between the bit lines can be smaller. Therefore, the size of the memory cell can be reduced, and the arrangement of the memory strings can be more compact, thereby increasing the storage capacity of the memory device and reducing the required volume of the semiconductor device.

In some embodiments, the channel structures 122 include a first channel layer 1221, a second channel layer 1222, a third channel layer 1223, a fourth channel layer 1224, a fifth channel layer 1225 and a sixth channel layer 1226. The first channel layer 1221 and the second channel layer 1222 correspond to the first memory string MS1 and are coupled to (for example, directly contacting and electrically connected to) the first conductive pillars 126a and the second conductive pillars 126b. The first channel layer 1221 and the second channel layer 1222 may be physically separated from each other by the first conductive pillar 126a and the second conductive pillar 126b. The third channel layer 1223 and the fourth channel layer 1224 correspond to the second memory string MS2 and are coupled to (for example, directly contacting and electrically connected to) the second conductive pillar 126b and the third conductive pillar 126c. The third channel layer 1223 and the fourth channel layer 1224 may be physically separated from each other by the second conductive pillar 126b and the third conductive pillar 126c. The fifth channel layer 1225 and the sixth channel layer 1226 correspond to the third memory string MS3 and are coupled to (for example, directly contacting and electrically connected to) the third conductive pillar 126c and the fourth conductive pillar 126d. The fifth channel layer 1225 and the sixth channel layer 1226 may be physically separated from each other by the third conductive pillar 126c and the fourth conductive pillar 126d. The channel structures 122 corresponding to the first memory string MS1 and the second memory string MS2 are connected to the same conductive pillar (i.e. the second conductive pillar 126b). The channel structures 122 corresponding to the second memory string MS2 and the third memory string MS2 are connected to the same conductive pillar (i.e. the third conductive pillar 126c).

In some embodiments, the memory structures 116 are disposed between the stack S1 and the channel structures 122, between the stack S1 and the conductive pillars 126, and between the insulating layers 112 and the conductive layers 118. In the present embodiment, the memory structures 116 corresponding to different conductive pillars 126 and channel structures 122 are connected to each other. As shown in FIG. 5B, the memory structures 116 corresponding to the first memory string MS1 and the second memory string MS2 are connected to each other, the memory structures 116 corresponding to the second memory string MS2 and the third memory string MS3 are connected to each other. The memory structures 116, for example, continuously extend between the conductive layers 118 and the channel structures 122 and between the conductive layers 118 and the conductive pillars 126, surrounding the channel structures 122 and the conductive pillars 126, but the present invention is not limited thereto. In addition, the memory structures 116 may directly contact the conductive pillars 126 (including the first conductive pillar 126a, the second conductive pillar 126b, the third conductive pillar 126c, and the fourth conductive pillar 126d).

In some embodiments, the insulating pillars 124 include a first insulating pillar 1241, a second insulating pillar 1242 and a third insulating pillar 1243 corresponding to the first memory string MS1, the second memory string MS2, and the third memory string MS3, respectively. The first insulating pillar 1241, the second insulating pillars 1242, and the third insulating pillar 1243 extend along the first direction, respectively. The first insulating pillar 1241 is disposed between the first conductive pillar 126a, the second conductive pillar 126b, the first channel layer 1221 and the second channel layer 1222. The second insulating pillar 1242 is disposed between the second conductive pillar 126b, the third conductive pillar 126c, the third channel layer 1223 and the fourth channel layer 1224. The third insulating pillar 1243 is disposed between the third conductive pillar 126c, the fourth conductive pillar 126d, the fifth channel layer 1225 and the sixth channel layer 1226. The adjacent ones of the conductive pillars 126 are electrically isolated from each other by the corresponding one of the insulating pillars 124, for example. The conductive pillars 126 may directly contact the insulating pillars 124. The connection line between the center points of the first conductive pillar 126a, the second conductive pillar 126b, the third conductive pillar 126c, and the fourth conductive pillar 126d, for example, penetrate the center points of the first insulating pillar 1241, the second insulating pillar 1242, and the third insulating pillar 1243.

FIG. 6 is a top view of a memory device 20 according to another embodiment of the present invention. The memory device 20 has a structure similar to that of the memory device 10, and the difference between the memory devices 20 and 30 is the cross-sectional shapes of the first conductive pillar 126al, the second conductive pillar 126bl, the third conductive pillar 126cl, and the fourth conductive pillar 126dl.

In the process of forming the memory device 20, an overlap area between adjacent vertical channel openings is larger than an overlap area between the openings 120 as shown in FIG. 1B, so compared to the memory device 10, the distance between the center points of adjacent memory strings MS of the memory device 20 is smaller, and the memory strings MS of the memory device 20 has a smaller width in the second direction, that is, the memory cell has a smaller size, and the arrangement of the memory strings can be closer, so that the storage capacity of the memory device 20 is further increased. In the present embodiment, the cross-sections of the first conductive pillar 126al, the second conductive pillar 126bl, the third conductive pillar 126cl, and the fourth conductive pillar 126dl are oval.

FIG. 7 is a top view of a memory device 30 according to another embodiment of the present invention. The memory device 30 has a structure similar to that of the memory device 10, and the difference between the memory devices 30 and 10 is the distance between the center points of adjacent memory strings.

In the process of forming the memory device 30, the vertical channel openings are disposed along the second direction and separated from each other. Therefore, compared with the memory device 10, the memory strings MS of the memory device 30 has a larger width in the second direction, and a total width formed by a plurality of memory structures 11611 connected to each other in the second direction is also larger, and a distance between the center points of adjacent memory strings MS is also larger.

FIG. 8 is a top view of a memory device 40 according to a further embodiment of the present invention. The memory device 40 has a structure similar to that of the memory device 10, and the difference between the memory devices 40 and 10 is the cross-sectional shape of the memory strings MS.

In the process of forming the memory device 40, the cross-section of the vertical channel openings is rectangular, so the channel structures 12211, the insulating pillars 12411, and the conductive pillars 12611 formed later may have a rectangular cross-section. A plurality of memory strings MS are disposed along the second direction and connected to each other to form a row of memory strings MS having a flat and stripe-like shape. Different rows of the memory strings MS are separated from each other in the third direction. Compared with the memory device 10, the different rows of memory strings MS of the memory device 40 has a smaller pitch in the third direction, and the memory strings MS in the same row has a smaller width in the second direction. That is, the memory cell has a smaller size, so that the arrangement of the memory strings can be closer, and the storage capacity of the memory device 40 can be increased. In a memory string MS, a maximum width W1 of the conductive pillar 12611 (including the first conductive pillar) in the third direction is the same as a maximum width W2 of the channel structures 12211 (including the first channel layer and the second channel layer) formed in the third direction.

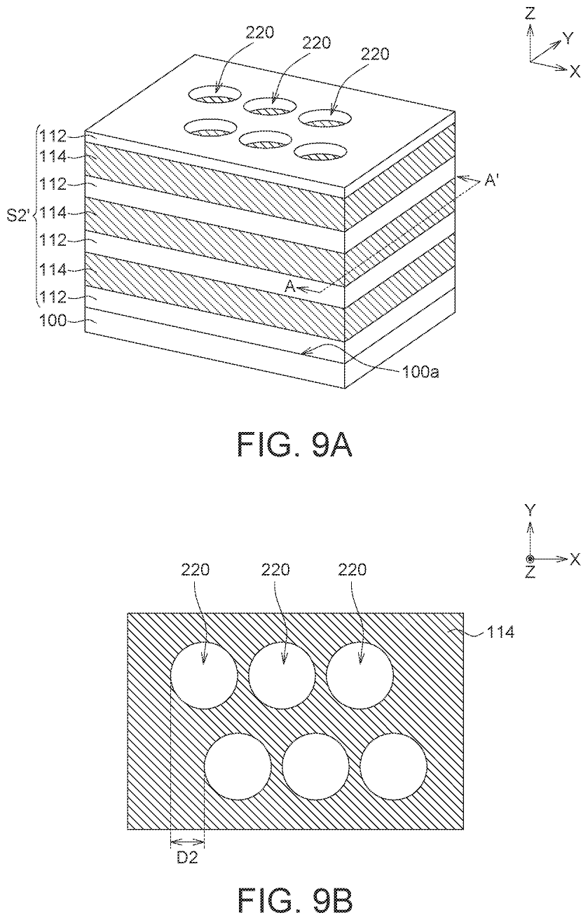

FIGS. 9A to 13B show schematic diagrams of a method for manufacturing a memory device 50 according to another embodiment of the present invention. FIGS. 9A, 10A, 11A, 12A, and 13A show three-dimensional views of the method for manufacturing the memory device 50, that is, three-dimensional views formed by the first direction (for example, Z direction), the second direction (for example, X direction), and the third direction (for example, Y direction). FIGS. 9B, 10B, 11B, 12B, and 13B show cross-sectional views taken along line A-A′ of FIGS. 9A, 10A, 11A, 12A, and 13A, respectively, that is, top views formed by the second direction (for example, X direction) and the third direction (for example, Y direction). The first direction, the second direction, and the third direction may be intersected with each other, for example, are perpendicular to each other.

Firstly, referring to FIGS. 9A and 9B at the same time, a laminated structure S2′ is provided on an upper surface 100a of a substrate 100. The laminated structure S2′ includes a plurality of insulating layers 112 and a plurality of sacrificial layers 114 alternately stacked along a first direction (for example, Z direction, or a normal direction of an upper surface 100a of the substrate 100). The insulating layers 112 and the sacrificial layers 114 are formed, for example, by deposition processes. Thereafter, a plurality of openings 220 penetrating the laminated structure S2′ along the first direction (for example, Z direction) are formed by an etching process. The bottom of each of the openings 220 exposes a portion of the upper surface 100a of the substrate 100. A portion of the openings 220 are disposed along the second direction and separated from each other to form a row of openings 220. Different rows of the openings 220 are separated along the third direction, and there is an offset distance D2 in the second direction between two adjacent rows of the openings 220. In other embodiments, the openings 220 in the same row may be disposed along the second direction and connected to each other. In FIGS. 9A and 9B, only two rows of the openings 220 are exemplarily shown, and each row of the openings 220 includes three openings 220. However, the number of rows of the openings 220 in the present invention and the number of the openings 220 included in each row of the openings 220 are not limited thereto. The openings 220 may also be referred to as vertical channel openings.

In the present embodiment, the openings 220 have a circular cross-section in the top view of FIG. 9B, but the present invention is not limited thereto. The cross-section of the openings 220 in the top view of FIG. 9B may be oval, rectangular or other suitable geometric shapes.

In some embodiments, the substrate 100 is, for example, a dielectric layer (for example, a silicon oxide layer), a silicon substrate or other suitable substrate. The insulating layers 112 may be, for example, oxide layers, and the oxide layers may include silicon dioxide. The sacrificial layers 114 may be, for example, nitride layers, and the nitride layers may include silicon nitride. In the present embodiment, the top and bottom layers of the laminated structure S2′ are insulating layers 112, and the laminated structure S2′ includes four insulating layers 112 and three sacrificial layers 114, but the present invention is not limited thereto. The number of layers 112 and sacrificial layer 114 can be adjusted according to requirements.

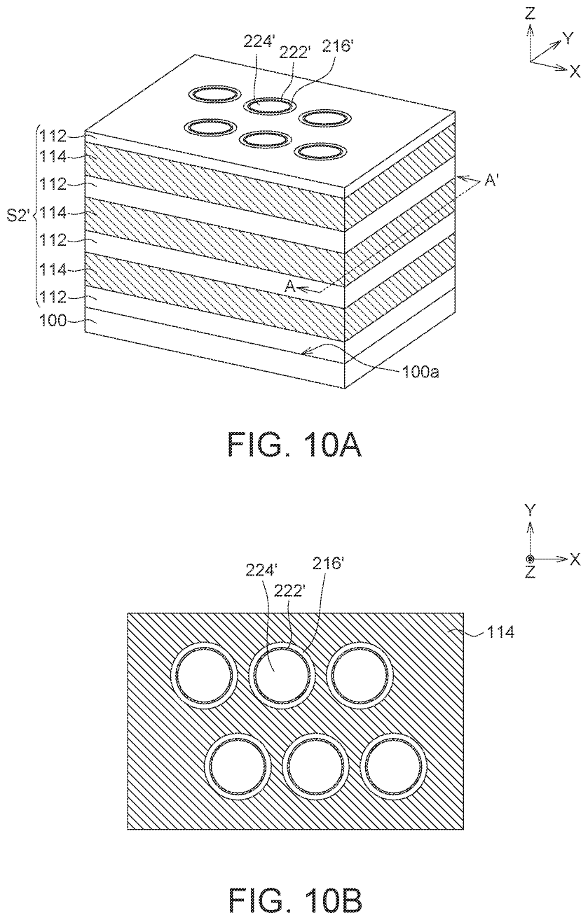

Next, referring to FIGS. 10A and 10B at the same time, a memory material 216′, a channel material 222′, and an insulating material 224′ are filled in the openings 220 in sequence. For example, the memory material 216′ can be formed on the sidewalls of the openings 220 by a deposition process, and a portion of the substrate 100 can be exposed by the memory material 216′. Then, the channel material 222′ can be formed on the sidewalls of the openings 220 having the memory material 216′ by a deposition process, and a portion of the substrate 100 can be exposed by the channel material 222′. The memory material 216′ and the channel material 222′ are conformal to the shape of the openings 220, and then the insulating material 224′ is filled in the openings 220 having the memory material 216′ and the channel material 222′ by a deposition process.

In some embodiments, the memory material 216′ may include oxide-nitride-oxide, ferroelectric material, or other suitable memory materials. The channel material 222′ may include undoped polysilicon. The insulating material 224′ may include silicon oxide, such as silicon dioxide.

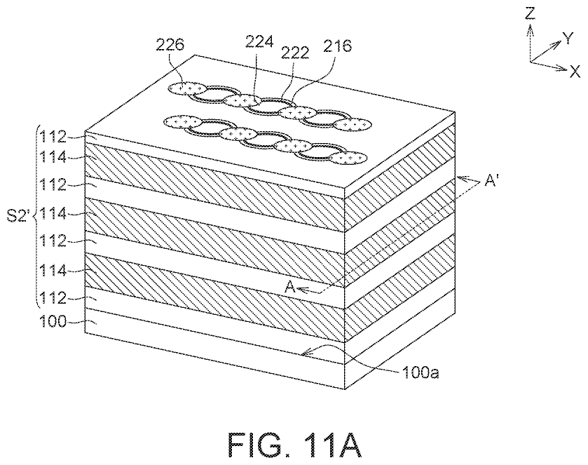

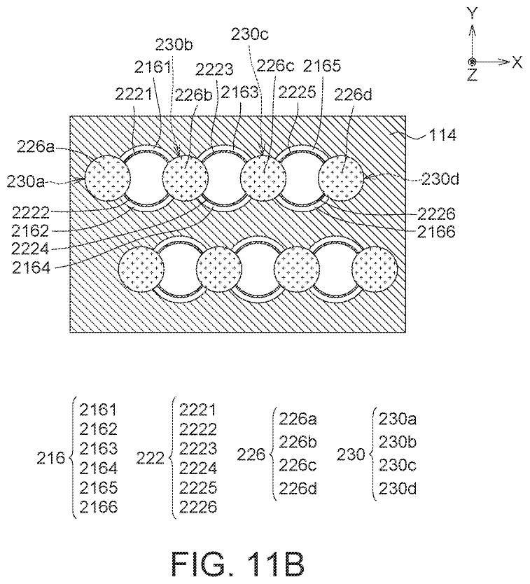

Next, referring to FIGS. 11A and 11B at the same time, portions of the memory material 216′, portions of the channel material 222′, portions of the insulating material 224′, portions of the insulating layers 112 and portions of the sacrificial layers 114 are removed along the first direction, to form a plurality of extending holes 230 disposed between adjacent ones of the openings 220 and disposed at the outermost two sides of the openings 220. The remaining portions of the channel material 222′ form a plurality of channel structures 222 connected to the extending holes 230. The remaining portions of the memory material 216′ form a plurality of memory structures 216 surrounding the channel structure 222. The remaining portions of the insulating material 224′ form a plurality of insulating pillars 224 disposed between the extending holes 230 and the channel structures 222, wherein the extending holes 230 and the openings 220 may be alternately disposed along the second direction and connected to each other.

For example, the extending holes 230 in the same row include extending holes 230b and 230c disposed at the center points of the boundarys of the adjacent ones of the openings 220, the extending hole 230a disposed at the leftmost side of the openings 220, and the extending hole 230b disposed at the rightmost side of the openings 220. The connection line between the center points of the extending holes 230a to 230d penetrates the center points of the openings 220, for example. The diameter of the extending holes 230 is smaller than the diameter of the openings 220. Thereafter, a conductive material is filled in the extending holes 230 to form a plurality of conductive pillars 226, wherein the conductive material is, for example, doped polysilicon. In the present embodiment, the conductive pillars 226 may include a first conductive pillar 226a, a second conductive pillar 226b, a third conductive pillar 226c, and a fourth conductive pillar 226d. The memory structures 216 may include a first memory layer 2161, a second memory layer 2162, a third memory layer 2163, a fourth memory layer 2164, a fifth memory layer 2165, and a sixth memory layer 2166. The channel structures 222 may include a first channel layer 2221, a second channel layer 2222, a third channel layer 2223, a fourth channel layer 2224, a fifth channel layer 2225, and a sixth channel layer 2226.

In some embodiments, after the conductive pillars 226 are formed, a planarization process may be performed, for example, the planarization process is Chemical-Mechanical Planarization (CMP).

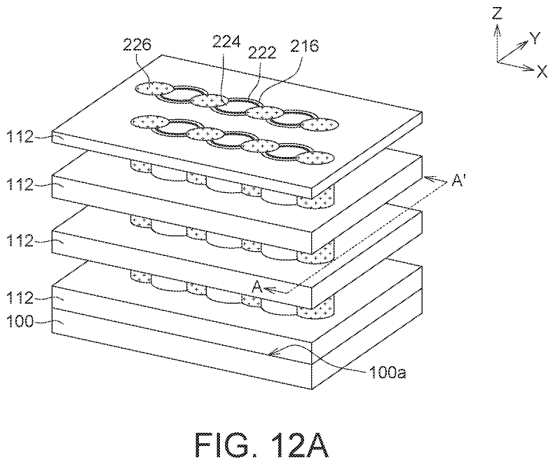

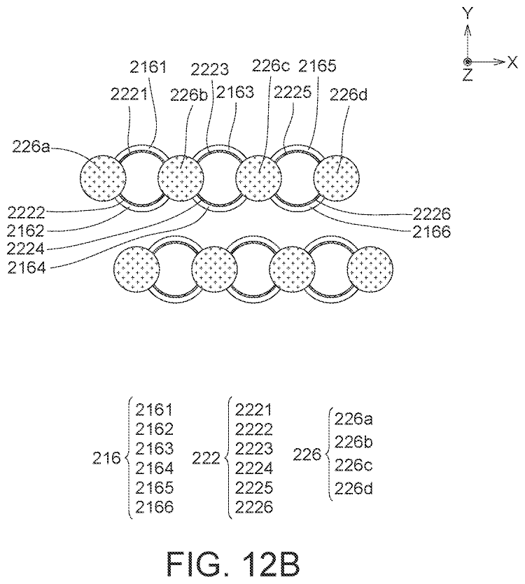

Next, referring to FIGS. 12A and 12B at the same time, the sacrificial layers 114 are removed to expose portions of the conductive pillars 226 and the memory structures 216. For example, the sacrificial layers 114 can be removed by a selective etching process, and the insulating layers 112 are remained.

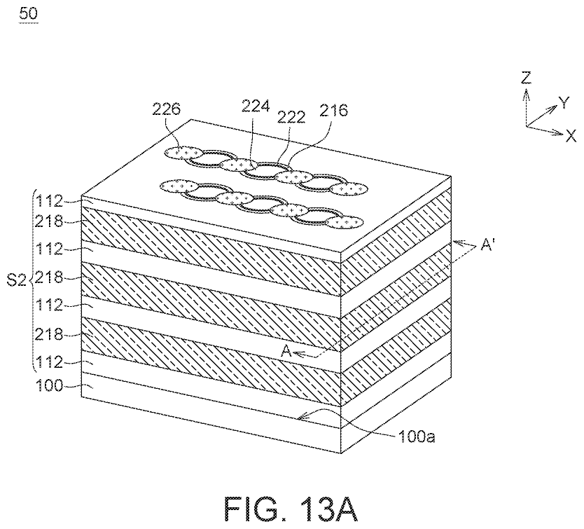

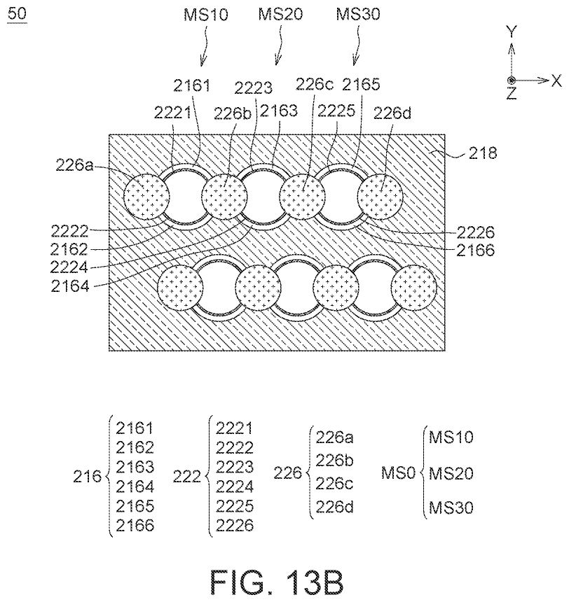

Thereafter, referring to FIGS. 13A and 13B at the same time, a plurality of conductive layers 218 alternately stacked with the insulating layers 112 are formed at the positions where the sacrificial layers 114 are removed, and the insulating layers 112 and the conductive layers 218 form a stack S2. In this way, a memory device 50 is formed. Each of the intersections between the memory structures 216, the channel structures 222, and the conductive layers 218 form a memory cell, and the plurality of memory cells form a plurality of memory strings MS0 extending along the first direction. In the present embodiment, the memory strings MS0 in the same row include a first memory string MS10, a second memory string MS20, and a third memory string MS30 that are adjacent to each other, but the present invention is not limited thereto. In some embodiments, the memory structures 216 may be a composite layer formed of an oxide layer-nitride layer-oxide layer, a ferroelectric material layer, or other suitable memory layer.

As shown in FIGS. 13A and 13B, the memory device 50 includes a stack S2 formed on the substrate 100 and a plurality of memory strings MS0. The stack S2 includes a plurality of insulating layers 112 and a plurality of conductive layers 218 alternately stacked. The memory strings MS0 respectively penetrate the stack S2 along the first direction. The memory strings MS0 form a plurality of rows of memory strings MS0 extending along the second direction (for example, the X direction) on the substrate 100, and the adjacent rows of the memory strings MS0 are separated from each other in the third direction (for example, Y direction). In the present embodiment, the memory strings MS0 in the same row includes a first memory string MS10, a second memory string MS20, and a third memory string MS30 that are adjacent to each other, but the number of the memory strings MS0 in a row of the present invention is not limited thereto. The first memory string MS10, the second memory string MS20, and the third memory string MS30 include a plurality of conductive pillars 226, a plurality of channel structures 222, and a plurality of memory structures 216.

In some embodiments, the conductive pillars 226 are disposed on two opposite sides of the corresponding one of the memory strings MO, for example. The conductive pillars 226 include a first conductive pillar 226a, a second conductive pillar 226b, a third conductive pillar 226c, and a fourth conductive pillar 226d that extend along the first direction and are electrically isolated from each other. The second conductive pillar 226b is disposed between the first conductive pillar 226a and the third conductive pillar 226c, and the third conductive pillar 226c is disposed between the second conductive pillar 226b and the fourth conductive pillar 226d. As shown in FIGS. 13A and 13B, the cross-sections of the first conductive pillar 226a, the second conductive pillar 226b, the third conductive pillar 226c, and the fourth conductive pillar 226d are circular, but the present invention is not limited thereto. The cross-sections of the first conductive pillar 226a, the second conductive pillar 126b, the third conductive pillar 226c, and the fourth conductive pillar 126d may be oval, rectangular or other suitable shapes. The first conductive pillar 226a, the second conductive pillar 226b, the third conductive pillar 226c, and the fourth conductive pillar 226d may be electrically connected to different bit lines (not shown), respectively. The first conductive pillar 226a and the second conductive pillar 226b can be used as a drain or a source of the first memory string MS10; the second conductive pillar 226b and the third conductive pillar 226c can be used as a drain or a source of the second memory string MS20; the third conductive pillar 226c and the fourth conductive pillar 226d can be used as a drain or a source of the third memory string MS30. In one embodiment, when the first conductive pillar 226a serves as the source of the first memory string MS10 and the second conductive pillar 226b serves as the drain of the first memory string MS10, the second conductive pillar 226b may serve as the source of the second memory string MS20. When the first conductive pillar 226a serves as the drain of the first memory string MS10 and the second conductive pillar 226b serves as the source of the first memory string MS10, the second conductive pillar 226b may serve as the drain of the second memory string MS20. In other words, the first memory string MS10 and the second memory string MS20 share the second conductive pillar 226b; the second memory string MS20 and the third memory string MS30 share the third conductive pillar 226c. Compared with the comparative example in which the memory strings are separated from each other and do not share any conductive pillars, since the adjacent ones of the memory strings MS0 in the memory device 50 of the present invention can share a conductive pillar 226, a pitch between the bit lines may be smaller, the size of the memory cell can be reduced, such that the arrangement of the memory strings may be more compact, thereby increasing the storage capacity of the memory device.

The memory device 50 is similar to the memory device 10, and the difference therebetween is the structure of the memory structures 216, and other identical or similar features will not be described in detail. As shown in FIGS. 13A and 13B, the memory structures 216 corresponding to the first memory string MS10, the second memory string MS20, and the third memory string MS30 are separated from each other. For example, the first memory layer 2161 and the second memory layer 2162 corresponding to the first memory string MS10 are separated from the third memory layer 2163 and the fourth memory layer 2164 corresponding to the second memory string MS20, the third memory layer 2163 and the fourth memory layer 2164 corresponding to the second memory string MS20 are separated from the fifth memory layer 2165 and the sixth memory layer 2166 corresponding to the third memory string MS30. The memory structures 216 continuously extend and penetrate the conductive layers 218 and the insulating layers 112 along the first direction.

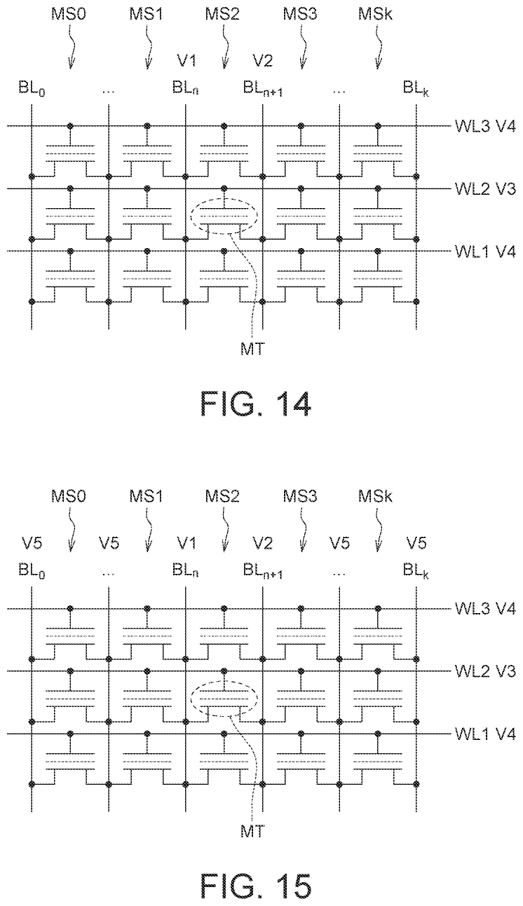

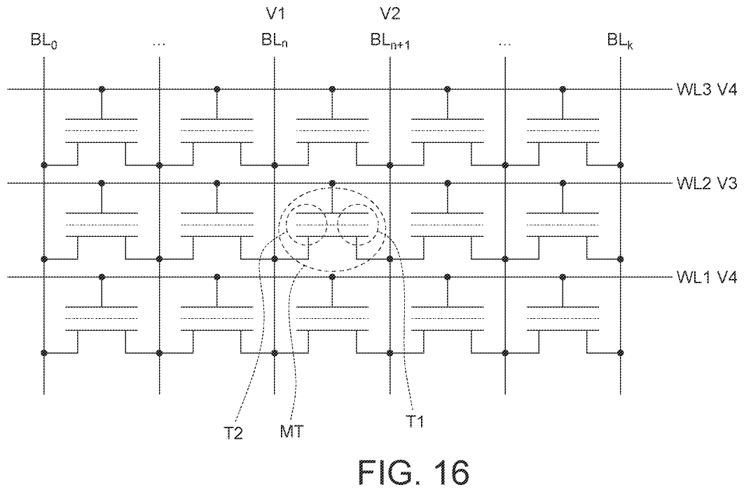

FIGS. 14 to 16 show equivalent circuit diagrams of a method for operating the memory device. FIG. 14 shows a read operation or a programming operation performed to a specific memory cell MT in the memory device. FIG. 15 shows an erase operation performed to the specific memory cell MT in the memory device. FIG. 16 shows the read operation or programming operation performed to a specific bit of the specific memory cell MT in the memory device. The memory device may be the memory devices 10 to 50 according to any embodiment of the present invention or other suitable memory devices.

In the memory device of the present invention, a plurality of memory strings MS are disposed along the second direction on a substrate (not shown) and connected to each other, and the conductive layers (for example, conductive layers 118 or 218) can be used as word lines WL1 to WL3 and the conductive pillars (for example, the conductive pillars 126 or 226) can be electrically connected to the corresponding one of the bit lines BL₀ . . . BLₙ, Bₙ₊₁ . . . BL_{K}, respectively, wherein n or k is a positive integer. Adjacent ones of the memory strings MS share a conductive pillar (that is, share a bit line).

As shown in FIGS. 14 to 16, the memory strings MS includes an initial memory string MS0, a first memory string MS1, a second memory string MS2, a third memory string MS3, a kₜ, memory string MSK and other memory strings (not shown). The first memory string MS1 and the second memory string MS2 share a conductive pillar (for example, a second conductive pillar) and a bit line BLₙ, and the second memory string MS2 and the third memory string MS3 share a conductive pillar (for example, a third conductive pillar) and a bit line BLₙ₊₁. If a read operation, a programing operation (for example, by Channel Hot Electron Injection) or an erase operation (for example, by Fowler-Nordheim tunneling, FN-tunneling) is desired to be performed to a specific memory cell MT of the second memory string MS2, a first voltage V1 is applied to the second conductive pillar through the bit line BLₙ; a second voltage V2 is applied to the third conductive pillar through the bit line BLₙ₊₁; a third voltage V3 is applied to the conductive layer (that is, the word line WL2) coupled to the specific memory cell MT; a fourth voltage V4 is applied to the conductive layers (that is, the word lines WL1 and WL3) that are not coupled to the specific memory cell MT. An absolute value of the third voltage V3 is greater than an absolute value of the fourth voltage V4. That is, the bit lines BLₙ and BLₙ₊₁ coupled to the specific memory cell MT are selected bit lines; the other bit lines BL₀, BL_{K} . . . which are not coupled to the specific memory cell MT are unselected bit lines. The word line WL2 coupled to the specific memory cell MT is the selected word line; the other word lines WL1 and WL3 that are not coupled to the specific memory cell MT are unselected word lines.

As shown in FIG. 14, when a read operation is desired to be performed to a specific memory cell MT in the second memory string MS2, the second voltage V2 is higher than the first voltage V1, and a difference between the second voltage V2 and the first voltage V1 is between 0.1V and 2V. For example, the first voltage V1 is 0V; the second voltage V2 is between 0.1V and 2V; the unselected bit lines BL₀, BL_{K} . . . are floating, that is, no voltage is applied to the unselected bit lines BL₀, BL_{K} . . . ; the third voltage V3 is higher than the fourth voltage V4, for example, the third voltage V3 is between 3V and 7V, and the fourth voltage V4 is 0V. In some embodiments, 0V can also be applied to the unselected bit lines BL₀, BL_{K} . . . .

As shown in FIG. 14, when a programming operation is desired to be performed to the specific memory cell MT in the second memory string MS2, the second voltage V2 is higher than the first voltage V1, and a difference between the second voltage V2 and the first voltage V1 is between 3V and 5V. For example, the first voltage V1 is 0V; the second voltage V2 is between 3V and 5V; the unselected bit lines BL₀, BL_{K} . . . are floating, that is, no voltage is applied to the unselected bit lines BL₀, BL_{K} . . . ; the third voltage V3 is higher than the fourth voltage V4, for example, the third voltage V3 is between 5V and 10V, and the fourth voltage V4 is 0V. In some embodiments, 0V can also be applied to the unselected bit lines BL₀, BL_{K} . . . .

As shown in FIG. 15, when an erase operation is desired to be performed to the specific memory cell MT in the second memory string MS2, the second voltage V2 is equal to the first voltage V1, for example, between 6V and 10V; the third voltage V3 is lower than the fourth voltage V4, for example, the third voltage V3 is between −6V and −10V, the fourth voltage V4 is 0V; the other bit lines BL₀, BL_{K} . . . that are not coupled to the specific memory cell MT are unselected bit lines, and a fifth voltage V5 is applied to the bit lines BL₀, BL_{K} . . . , respectively, and the fifth voltage V5 is equal to the first voltage V1 and the second voltage V2, for example, between 6V and 10V.

As shown in FIG. 16, a specific memory cell MT includes two bits, that is, a first bit T1 and a second bit T2. The first bit T1 and the second bit T2 may be disposed in the same memory layer and are disposed at two opposite sides (for example, the right side and the left side). The first bit T1 is closer to the third conductive pillar and the bit line BLₙ₊₁ in comparison with the second bit T2. The second bit T2 is closer to the second conductive pillar and the bit line BLₙ in comparison with the first bit T1.

When a read operation is desired to be performed to the first bit T1 of the specific memory cell MT, the first voltage V1 is higher than the second voltage V2, and the difference between the second voltage V2 and the first voltage V1 is between 0.1V to 2V. For example, the first voltage V1 is between 0.1V and 2V; the second voltage V2 is 0V; the third voltage V3 is higher than the fourth voltage V4, for example, the third voltage V3 is between 3V and 7V, the fourth voltage V4 is 0V, and the other bit lines BL₀, BL_{K} . . . that are not coupled to the specific memory cell MT are unselected bit lines, and bit lines BL₀, BL_{K} . . . are floating, that is, no voltage is applied to bit lines BL₀, BL_{K} . . . . In some embodiments, 0V can also be applied to the unselected bit lines BL₀, BL_{K} . . . .

When a programming operation is desired to be performed to the first bit T1 of the specific memory cell MT, the second voltage V2 is higher than the first voltage V1; the difference between the second voltage V2 and the first voltage V1 is between 3V to 5V, for example, the first voltage V1 is 0V and the second voltage is between 3V and 5V; the third voltage V3 is higher than the fourth voltage V4, for example, the third voltage V3 is between 5V and 10V and the fourth voltage V4 is 0V.

When a read operation is desired to be performed to the second bit T2 of the specific memory cell MT, the second voltage V2 is higher than the first voltage V1; the difference between the first voltage V1 and the second voltage V2 is between 0.1V to 2V, for example, the first voltage V1 is 0V and the second voltage V2 is between 0.1V and 2V; the third voltage V3 is higher than the fourth voltage V4, for example, the third voltage V3 is between 3V and 7V, and the fourth voltage V4 is 0V.

When a programming operation is desired to be performed to the second bit T2 of the specific memory cell MT, the first voltage V1 is higher than the second voltage V2; the difference between the first voltage V1 and the second voltage V2 is between 3V to 5V, for example, the first voltage V1 is between 3V and 5V, the second voltage V2 is 0V; the third voltage V3 is higher than the fourth voltage V4, for example, the third voltage V3 is between 5V and 10V, and the fourth voltage V4 is 0V.

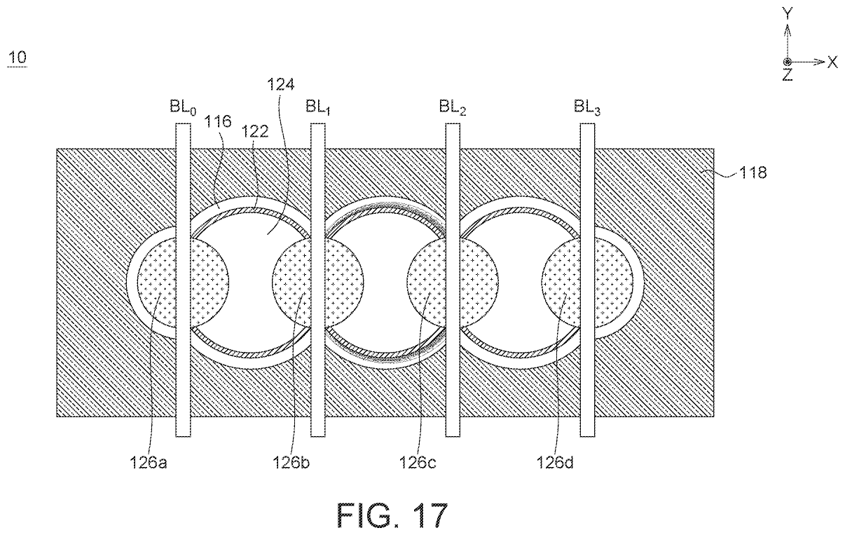

FIGS. 17-19 show the simulation results when a programming operation is performed to the first bit T1 of the specific memory cell MT.

Referring to FIG. 17, which shows a simple schematic diagram of the distribution of electrons in the memory device 10 for performing a programming operation to the first bit T1 of the specific memory cell MT of the memory string MS2. The denser the dots means the more electrons are captured. The first conductive pillar 126a, the second conductive pillar 126b, the third conductive pillar 126c, and the fourth conductive pillar 126d are electrically connected to the bit lines BL₀, BL₁, BL₂, and BL₃, respectively. In the present embodiment, 0V is applied to the second conductive pillar 126b through the bit line BL₁, 5V is applied to the third conductive pillar 126c through the bit line BL₂, and 10V is applied to the conductive layer 118 coupled to the specific memory cell MT. 0V is applied to the conductive layers 118 not coupled to the specific memory cell MT. As shown in FIG. 17, in the specific memory cell MT of the memory string MS2, the first bit T1 disposed on the right side has a higher density of dots, indicating that under the programming operation, the electrons are indeed gathered closer to the third conductive pillar 126c and the bit line BL₂.

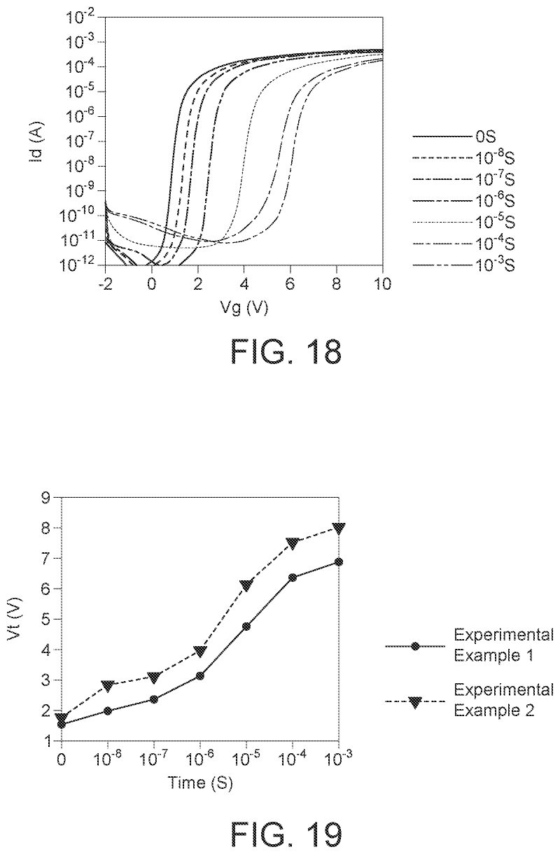

Referring to FIG. 18, it shows the relationship between the current and the voltage at different times (for example, 0 second, 10⁻⁸ seconds, 10⁻⁷ seconds, 10⁻⁶ seconds, 10⁻⁵ seconds, 10⁻⁴ seconds and 10⁻³ seconds) according to the conditions of the programming operation described in FIG. 17 and related paragraphs. The Y axis represents the current Id (amperes) of the bit line BL₂, and the X axis represents the voltage Vg (volts) of the word line coupled to the specific memory cell MT. It can be seen that as time increases (for example, from 0 second to 10$ seconds), the threshold voltage increases.

Referring to FIG. 19, it shows the relationship between the threshold voltage Vt and time Examples 1-2. The Y axis represents the threshold voltage Vt when the current of the bit line BL₂ is 10 μA, and the X axis represents time (second, S). Experimental example 1 shows the variation of the threshold voltage Vt at different times according to the conditions of the programming operation described in FIG. 17 and related paragraphs (for example, applying 5V to the bit line BL₂). The difference between Experimental Example 2 and Experimental Example 1 is that 7V is applied to the bit line BL₂. As shown in FIG. 19, as time increases, the threshold voltage Vt gradually increases. When the voltage applied to the bit line BL₂ increases, the threshold voltage Vt increases faster.

According to the foregoing contents, the present invention provides a memory device. The memory device includes a stack and a plurality of memory strings. The stack is formed on a substrate, and the stack includes a plurality of insulating layers and a plurality of conductive layers stacked alternately. The memory strings penetrate the stack along a first direction respectively. The memory strings include a first memory string and a second memory string adjacent to each other, wherein the first memory string and the second memory string include a plurality of conductive pillars, a plurality of channel structures, and a plurality of memory structures. The conductive pillars include a first conductive pillar, a second conductive pillar, and a third conductive pillar respectively extending along the first direction and electrically isolated from each other. The second conductive pillar is disposed between the first conductive pillar and the third conductive pillar. The first memory string and the second memory string share the second conductive pillar. The channel structures include a first channel layer, a second channel layer, a third channel layer, and a fourth channel layer respectively extending along the first direction, wherein the first channel layer and the second channel layer correspond to the first memory string and are coupled to the first conductive pillar and the second conductive pillar, and the first channel layer and the second channel layer are separated from each other. The third channel layer and the fourth channel layer correspond to the second memory string and are coupled to the second conductive pillar and the third conductive pillar, and the third channel layer and the fourth channel layer are separated from each other. The memory structures are disposed between the stack and the channel structures.

In comparison with the comparative example in which the memory strings are separated from each other and do not share any conductive pillars, since the adjacent memory strings in the memory device of the present application can share a conductive pillar, such that a pitch between the bit lines may be decreased, the size of the memory cells may be reduced, and the arrangement of the memory strings may be more compact, thereby increasing the storage capacity of the memory device.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A memory device, comprising:
a stack formed on a substrate, the stack comprising a plurality of insulating layers and a plurality of conductive layers stacked alternately; and
a plurality of memory strings penetrate the stack along a first direction, respectively, and the memory strings comprising a first memory string and a second memory string adjacent to each other, wherein the first memory string and the second memory string comprises a plurality of conductive pillars, a plurality of channel structures, and a plurality of memory structures;
wherein the conductive pillars comprises a first conductive pillar, a second conductive pillar, and a third conductive pillar extending along the first direction and electrically isolated from each other, wherein the second conductive pillar is disposed between the first conductive pillar and the third conductive pillar, and the first memory string and the second memory string share the second conductive pillar;
wherein the channel structures include a first channel layer, a second channel layer, a third channel layer, and a fourth channel layer respectively extending along the first direction, wherein the first channel layer and the second channel layer correspond to the first memory string and are coupled to the first conductive pillar and the second conductive pillar, the first channel layer and the second channel layer are separated from each other; wherein the third channel layer and the fourth channel layer correspond to the second memory string and are coupled to the second conductive pillar and the third conductive pillar, the third channel layer and the fourth channel layers are separated from each other; and
wherein the memory structures are disposed between the stack and the channel structures.

2. The memory device according to claim 1, wherein the memory structures directly contact the first conductive pillar, the second conductive pillar and the third conductive pillar.

3. The memory device according to claim 1, wherein the memory structures corresponding to the first memory string and the second memory string are separated from each other.

4. The memory device according to claim 1, wherein cross-sections of the first conductive pillar, the second conductive pillar and the third conductive pillar are circular, oval or rectangular.

5. The memory device according to claim 1, wherein the memory strings form a plurality of rows of the memory strings extending along a second direction on the substrate, adjacent rows of the memory strings are separated from each other in a third direction, and the first direction, the second direction and the third direction are perpendicular to each other,
wherein, a maximum width of the first conductive pillar in the third direction is equal to a maximum width formed by the first channel layer and the second channel layer in the third direction.

6. A method for manufacturing a memory device, comprising:
providing a laminated structure on a substrate, the laminated structure comprising a plurality of insulating layers and a plurality of sacrificial layers stacked alternately;
forming a plurality of openings penetrating the laminated structure along a first direction;
sequentially filling a channel material and an insulating material in the openings;
removing portions of the channel material, portions of the insulating material, portions of the insulating layers, and portions of the sacrificial layers along the first direction so as to form a plurality of extending holes disposed between adjacent ones of the openings and disposed at outermost two sides of the openings, and remaining portions of the channel material forming a plurality of channel structures connected to the extending holes, wherein the extending holes and the openings are alternately disposed along a second direction and connected to each other, the second direction is perpendicular to the first direction;
filling a conductive material in the extending holes to form a plurality of conductive pillars, the conductive pillars comprising a first conductive pillar, a second conductive pillar, and a third conductive pillar, wherein the second conductive pillar is disposed between the first conductive pillar and the third conductive pillar;
removing the sacrificial layers to expose portions of the conductive pillars and the channel structures;
sequentially forming a plurality of memory structures and a plurality of conductive layers alternately stacked with the insulating layers at positions where the sacrificial layers are removed, the insulating layers and the conductive layers forming a stack, the memory structures disposed between the stack and the channel structures, each of intersections between the memory structures, the channel structures, and the conductive layers forming a memory cell, and a plurality of the memory cells forming a plurality of memory strings extending along the first direction, respectively, the memory strings comprising a first memory string and a second memory string adjacent to each other, wherein the first memory string and the second memory string share the second conductive pillar.

7. The method for manufacturing the memory device according to claim 6, wherein portions of the openings are disposed along the second direction and are connected to each other.

8. The method for manufacturing the memory device according to claim 6, wherein after the step of forming the extending holes, a remaining portion of the insulating material forms a plurality of insulating pillars disposed between the extending holes and the channel structures.

9. The method for manufacturing the memory device according to claim 6, wherein the memory structures corresponding to the first memory string and the second memory string are connected to each other.

10. A method for manufacturing a memory device, comprising:
providing a laminated structure on a substrate, the laminated structure comprising a plurality of insulating layers and a plurality of sacrificial layers stacked alternately;
forming a plurality of openings penetrating the laminated structure along a first direction;
sequentially filling a memory material, a channel material and an insulating material in the openings;
removing portions of the memory material, portions of the channel material, portions of the insulating material, portions of the insulating layers, and portions of the sacrificial layers along the first direction so as to form a plurality of extending holes disposed between adjacent ones of the openings and disposed at outermost two sides of the openings, remaining portions of the channel material forming a plurality of channel structures connected to the extending holes, remaining portions of the memory material forming a plurality of memory structures, wherein the extending holes and the openings are alternately disposed along a second direction and connected to each other, the second direction is perpendicular to the first direction;
filling a conductive material in the extending holes to form a plurality of conductive pillars, the conductive pillars comprising a first conductive pillar, a second conductive pillar, and a third conductive pillar, wherein the second conductive pillar is disposed between the first conductive pillar and the third conductive pillar;
removing the sacrificial layers to expose portions of the conductive pillars and the memory structures;
forming a plurality of conductive layers alternately stacked with the insulating layers at positions where the sacrificial layers are removed, the insulating layers and the conductive layers forming a stack, the memory structures disposed between the stack and the channel structures, each of intersections between the memory structures, the channel structures, and the conductive layers forming a memory cell, and a plurality of the memory cells forming a plurality of memory strings along the first direction, respectively, the memory strings comprising a first memory string and a second memory string adjacent to each other, wherein the first memory string and the second memory string share the second conductive pillar.

11. The method for manufacturing the memory device according to claim 10, wherein portions of the openings are disposed along the second direction and are separated from each other.

12. The method for manufacturing the memory device according to claim 10, wherein after the step of forming the extending holes, a remaining portion of the insulating material forms a plurality of insulating pillars disposed between the extending holes and the channel structures.

13. The method for manufacturing the memory device according to claim 10, wherein the memory structures corresponding to the first memory string and the second memory string are separated from each other.

14. A method for operating a memory device, comprising:
providing a memory device according to claim 1, if a read operation, a programming operation or an erase operation is desired to be performed to a specific memory cell in the second memory string, a first voltage is applied to the second conductive pillar, a second voltage is applied to the third conductive pillar, a third voltage is applied to the conductive layer coupled to the specific memory cell, and a fourth voltage is applied to the conductive layers not coupled to the specific memory cell, wherein an absolute value of the third voltage is greater than an absolute value of the fourth voltage.

15. The method for operating the memory device according to claim 14, when the read operation is desired to be performed to the specific memory cell in the second memory string, the second voltage is higher than the first voltage, a difference between the second voltage and the first voltage is between 0.1V and 2V, and the third voltage is higher than the fourth voltage.

16. The method for operating the memory device according to claim 14, when the programming operation is desired to be performed to the specific memory cell in the second memory string, the second voltage is higher than the first voltage, a difference between the second voltage and the first voltage is between 3V and 5V, and the third voltage is higher than the fourth voltage.

17. The method for operating the memory device according to claim 14, when the erase operation is desired to be performed to the specific memory cell in the second memory string, the second voltage is equal to the first voltage, and the third voltage is lower than the fourth voltage.

18. The method for operating the memory device according to claim 14, wherein the specific memory cell comprises a first bit and a second bit, and the first bit is closer to the third conductive pillar in comparison with the second bit, the second bit is closer to the second conductive pillar in comparison with the first bit.

19. The method for operating the memory device according to claim 18, when the read operation is desired to be performed to the first bit of the specific memory cell, the first voltage is higher than the second voltage, a difference between the second voltage and the first voltage is between 0.1V and 2V, and the third voltage is higher than the fourth voltage.

20. The method for operating the memory device according to claim 18, when the programming operation is desire to be performed to the first bit of the specific memory cell, the second voltage is higher than the first voltage, a difference between the second voltage and the first voltage is between 3V and 5V, and the third voltage is higher than the fourth voltage.
